(19) United States
(12) Patent Application Publication
(10) Pub. No.: US 2015/0181716 A1
(43) Pub. Date: Jun. 25, 2015

(54) METHOD FOR MANUFACTURING TOUCH PANEL

(71) Applicant: HON HAI PRECISION INDUSTRY CO., LTD., New Taipei (TW)

(72) Inventors: TEN-HSING JAW, Zhubei (TW); CHIN-YANG WU, Zhubei (TW); SZU-WEI SUNG, New Taipei (TW); CHING-HO WEI, New Taipei (TW)

(21) Appl. No.: 14/576,373

(22) Filed: Dec. 19, 2014

(30) Foreign Application Priority Data
Dec. 25, 2013 (TW) 102148133

(51) Int. Cl. H05K 3/06; C23F 1/00

(52) U.S. Cl. CPC H05K 3/06; C23F 1/00

(57) ABSTRACT

A method for manufacturing a touch panel includes the following procedures. A base plate is provided. An indium tin oxide film is formed on the base plate. The indium tin oxide film is etched to form a plurality of first and second electrodes which are alternatively arranged according to columns on the base plate and insulated from each other, and the first electrodes in a column along a first direction are electrically coupled to each other. A plurality of insulated layers is formed on the first and second electrodes. A plurality of conductive connectors are formed on the plurality of insulated layers via an ink jet printing method to electrically interconnect with the second electrodes in a column along the second direction intersecting the first direction. The widths of the conductive connectors are reduced below 10 μm via a laser processing method.

### FIELD

The subject matter herein generally relates to a method for manufacturing a touch panel.

### BACKGROUND

Touch panels are input devices that allow manual instruction to be input by touching the screen.

### BRIEF DESCRIPTION OF THE DRAWINGS

Implementations of the present technology will now be described, by way of example only, with reference to the attached figures.

FIG. 1 is a top view of an embodiment of a touch panel.

FIG. 2 is an enlarged view of area II of FIG. 1.

FIG. 3 is a cross-sectional view of the touch panel of FIG. 2, along a line III-III of FIG. 2, including a base plate.

FIG. 4 is a cross-sectional view of the base plate of FIG. 3 after a process of first forming a film of conductive material.

FIG. 5 is a cross-sectional view of the touch panel of FIG. 4 after a process of etching the film.

FIG. 6 is a cross-sectional of the touch panel of FIG. 5 after a process of second forming an insulated layer.

FIG. 7 is a top view of the touch panel of FIG. 6.

FIG. 8 is a top view of the touch panel of FIG. 7 after a process of third forming conductive connectors.

FIG. 9 is a flowchart for manufacturing the touch panel of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

A method for manufacturing a touch panel can include: providing a base plate; forming an indium tin oxide film on the base plate; etching the indium tin oxide film to form a plurality of first and second electrodes which are alternatively arranged according to columns on the base plate and insulated from each other, the first electrodes in a column along a first direction can be electrically coupled to each other, the second electrodes in a column along a second direction intersecting the first direction can have separated patterns; forming a plurality of insulated layers on the first and second electrodes, each insulated layer can overlap a portion of each two neighboring second electrodes in a column along the second direction and a portion of each two first electrodes positioned adjacent to the two neighboring second electrodes; forming a plurality of conductive connectors on the plurality of insulated layers via an ink jet printing method to electrically interconnect with the second electrodes in a column along the second direction; and diminishing the widths of the plurality of conductive connectors below 10 μm via a laser processing method.

A method for manufacturing a touch panel can include: providing a base plate; first forming a film of conductive material on the base plate; etching the film to form a plurality of sections of substantially common shape and size in rows of a diamond matrix, each of the sections within a common row being electrically connected with each other and electrically isolated from adjacent ones of the sections in adjacent rows; second forming, over each congruence of four sections from two adjacent rows, an insulating layer; and third forming a conductive connector on top of each insulated layer to electrically connected two sections from adjacent rows. The first forming defines the sections as electrically connected rows and electrically isolated columns, and the third forming coverts the electrically isolated columns into electrically connected columns.

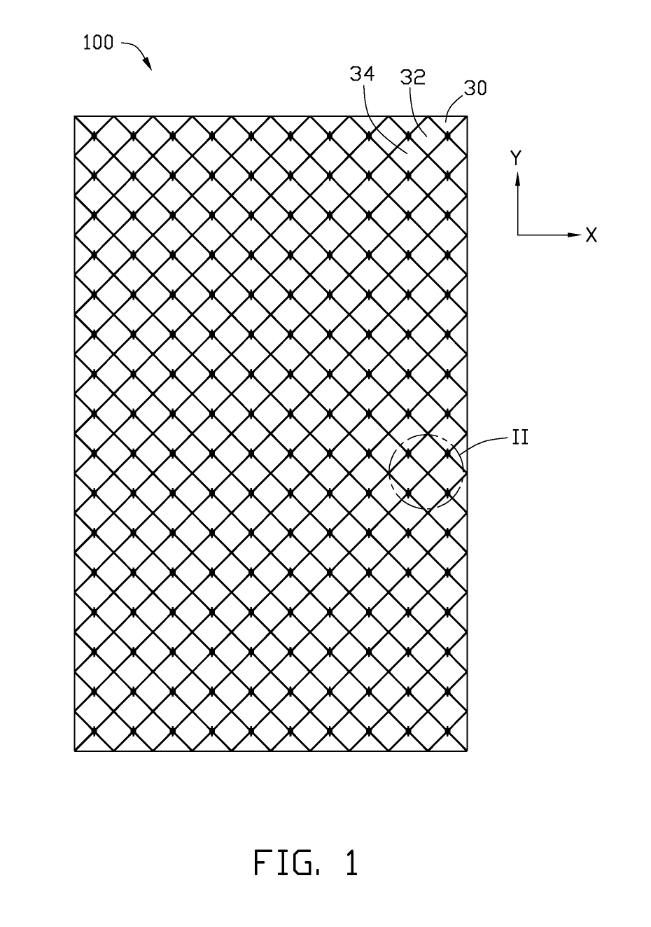

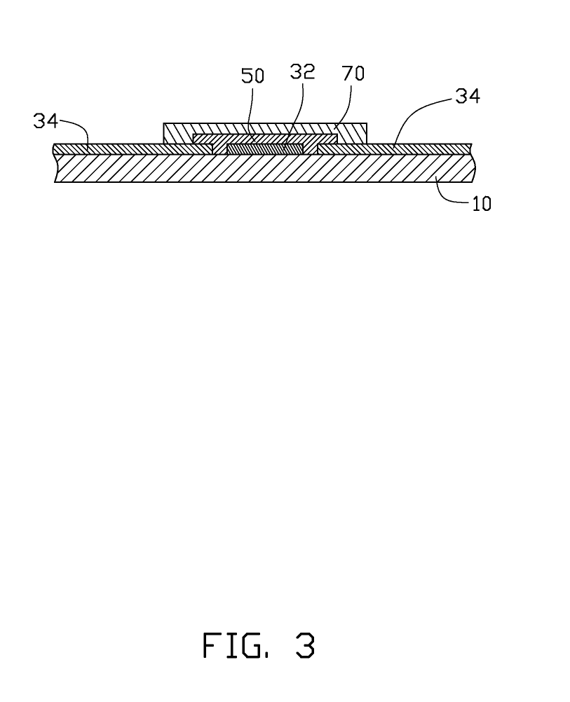

FIGS. 1 and 3 illustrate an embodiment of a touch panel 100. The touch panel 100 can include a base plate 10, an indium tin oxide film 30 formed on the base plate 10, a number of insulated layers 50, and a number of conductive connectors 70. In at least one embodiment, the base plate 10 can be made of a transparent insulation material, such as polyethylene terephthalate (PET). In at least one embodiment, the indium tin oxide film 30 can be other film made of conductive materials.

The indium tin oxide film 30 can define a number of first electrodes 32, and a number of second electrodes 34 arranged between and insulated from the first electrodes 32. The first electrodes 32 and the second electrodes 34 can be alternatively arranged according to columns, and can have substantially common shape and size in rows of a diamond matrix. In at least one embodiment, the first electrodes 32 and the second electrodes 34 can be respectively formed in mesh structures on the base plate 10. The first electrodes 32 can be drive electrodes, electrically coupled to each other in a column along a first direction X to form a drive electrode column, and insulated from each other in a column along a second direction Y which intersects the first direction X. The second electrodes 34 can be sensor electrodes, and dispersed between the first electrodes 32 to have separate patterns in a column along the second direction Y, thereby the second electrodes 34 can be insulated from the first electrodes 32 and can be insulated from each other. The second electrodes 34 can be electrically coupled to each other in a second direction Y via the conductive connectors 70 to form a sensor electrode column.

The indium tin oxide film 30 can be formed on the base plate 10 by a sputtering coating method. The first electrodes 32 and the second electrodes 34 can be formed on the base plate 10 by etching the indium tin oxide film 30. In at least one embodiment, the first electrodes 32 can be sensor electrodes, and the second electrode 34 can be drive electrodes.

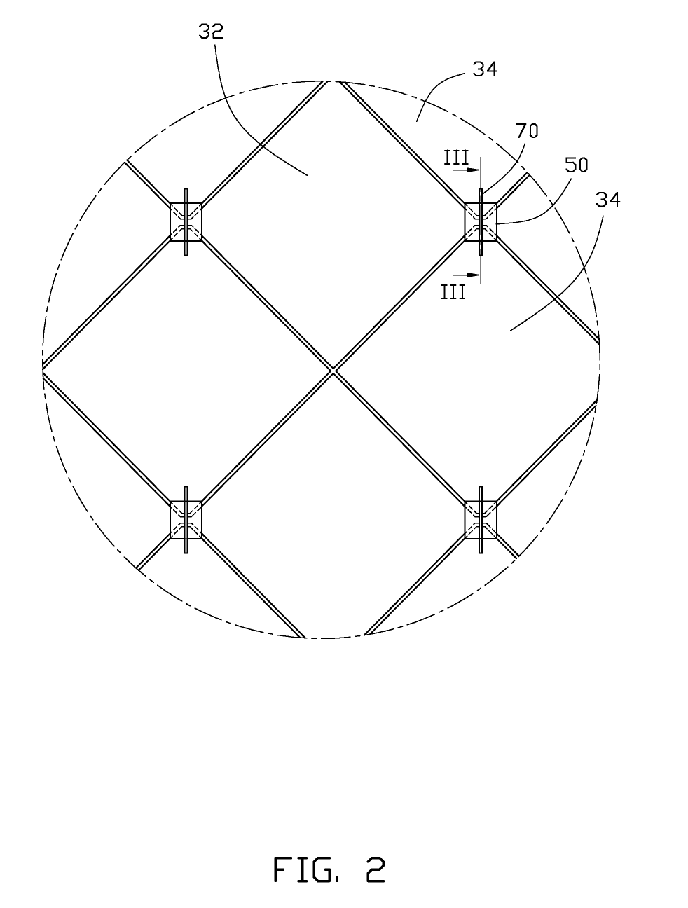

FIGS. 2 and 3 illustrate that the number of insulated layers 50 can be patterned on the first electrodes 32 and the second electrodes 34. Each insulated layer 50 can overlap a portion of each two neighboring second electrodes 34 in a column along the second direction Y to provide an insulation property. Each insulated layer 50 can overlap a portion of each two first electrodes 32, which can be positioned adjacent to the two neighboring second electrodes 34. Each insulated layer 50 can be substantially rectangular in shape. The insulated layers 50 can be made of transparent organic materials deposed via a ink jet printing method, which are thermosetting or UV-curing, such as poly(4 vinyl phenol), polyimide, aromatic either, or aromatic hydrocarbon, for example. In at least one embodiment, the insulated layers 50 can be in other shapes, such as triangular, hexagonal, or circular, so long as each insulated layer 50 can overlap a portion of each two neighboring second electrodes 34 along the second direction Y, and a portion of each two first electrodes 32 positioned adjacent to the two neighboring second electrodes 34

The conductive connectors 70 can be formed on the insulated layers 50. Each conductive connector 70 can be formed on one insulated layer 50, and two ends of the conductive connector 70 can protrude out from the corresponding insulated layer 50 to be electrically coupled to the two neighboring second electrodes 34 in a column along the second direction Y. Thereby, the second electrodes 34 arranged in a column along the second direction Y can be electrically coupled to each other. The conductive connectors 70 can be made of ink doped with metal conductive particles to provide a conduction property. In at least one embodiment, the metal conductive particles can be one or more materials selected from a group of silver nanoparticles, gold nanoparticles, copper nanoparticles. The conductive connectors 70 can be formed via an ink jet printing method and a laser processing method.

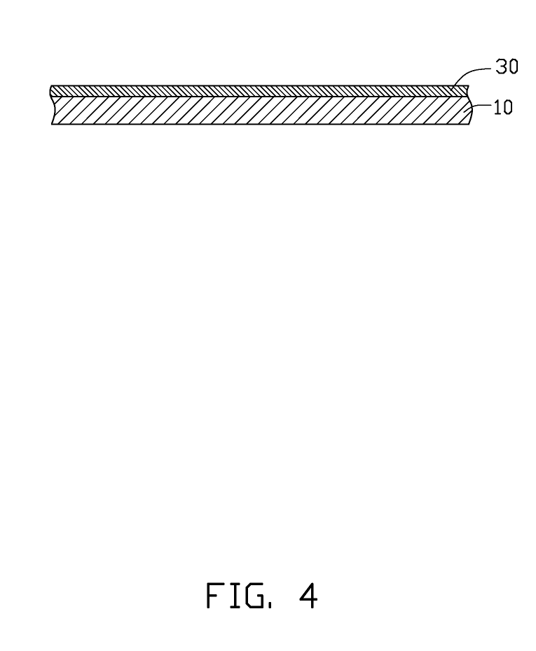

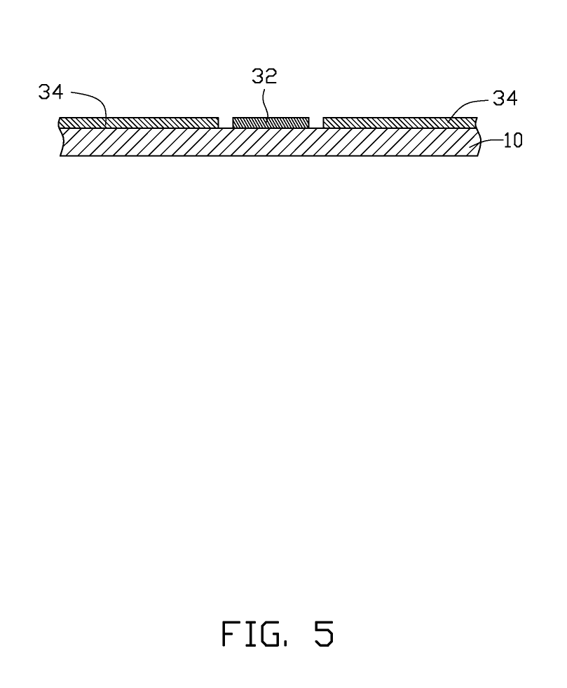

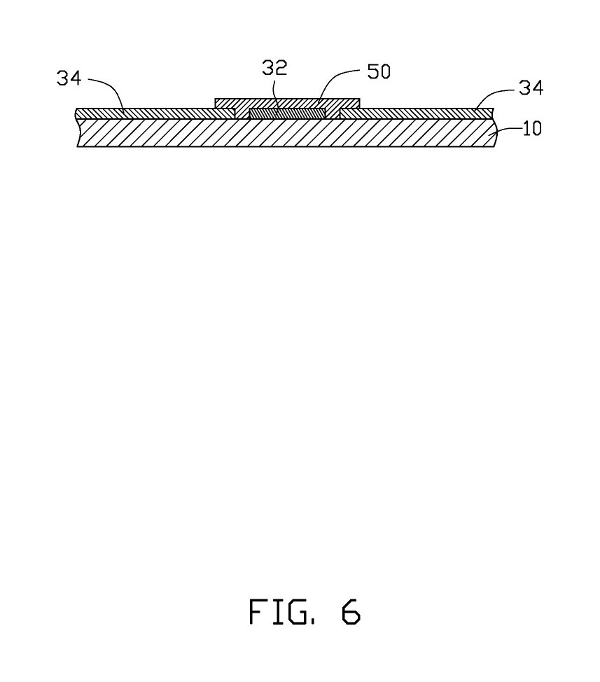

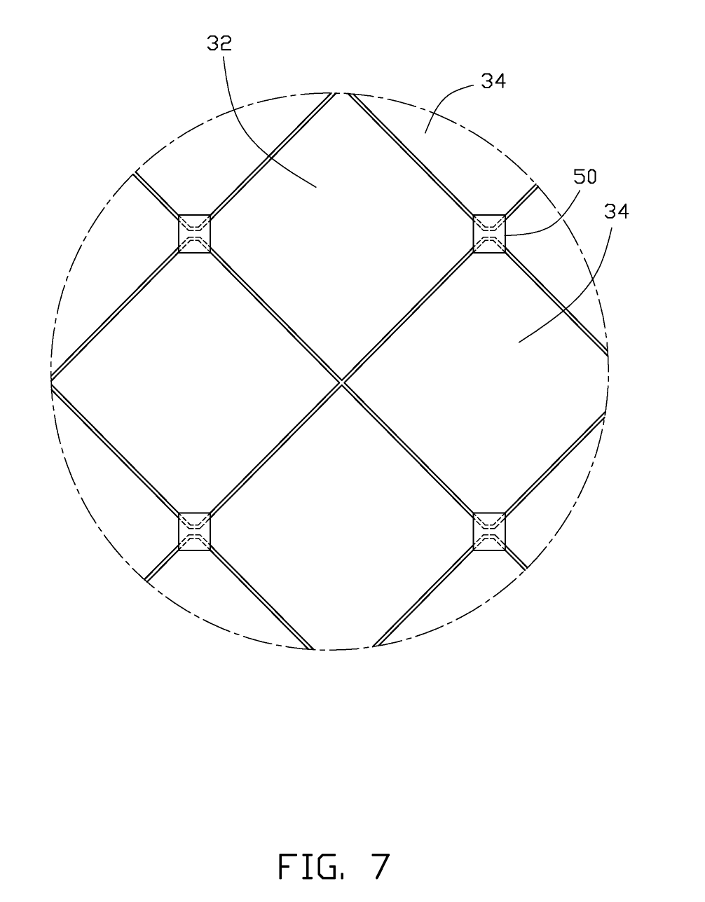

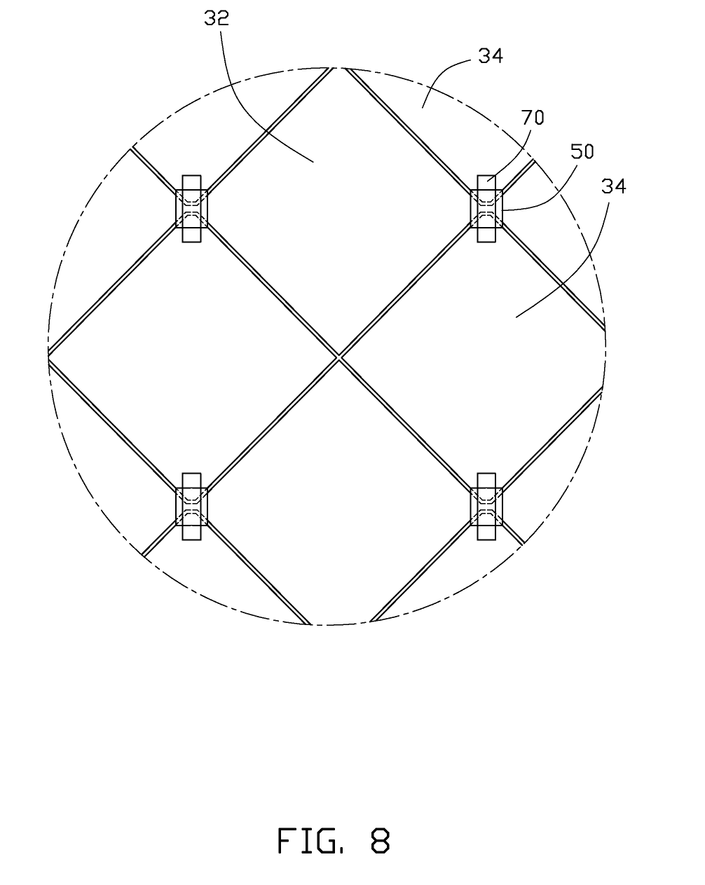

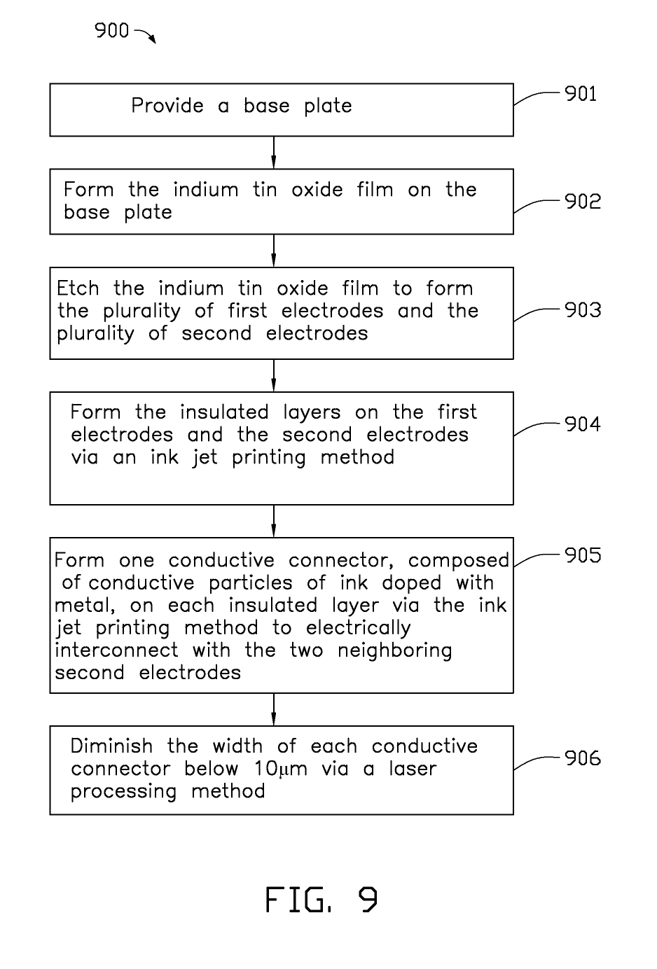

FIG. 9 illustrates the process and method for manufacturing the touch panel in accordance with an example embodiment. The example method 900 is provided by way of example, as there are a variety of ways to carry out the method. The method 900 described below can be carried out using the configurations illustrated in FIGS. 4-8 (concluding in the configurations illustrated in FIGS. 3 and 2, respectively) , for example, and various elements of these figures are referenced in explaining example method 900. Each block shown in FIG. 9 represents one or more processes, methods or subroutines, carried out in the example method 900. Furthermore, the illustrated order of blocks is by example only and the order of the blocks can change according to the present disclosure. Additional blocks may be added or fewer blocks may be utilized, without departing from this disclosure. The example method 900 for manufacturing the touch panel can begin at block 901.

At block 901, a base plate is provided. In at least one embodiment, the base plate 10 can be made of transparent glass.

At block 902, the indium tin oxide film is formed on the base plate. In at least one embodiment, the indium tin oxide film 30 can be coated on the base plate 10 by a sputtering coating method, and the indium tin oxide film 30 can be other film made of conductive materials

At block 903, the plurality of first electrodes and the plurality of second electrodes are formed via etching the indium tin oxide film.

The first electrodes 32 and the second electrodes 34 can be respectively formed in mesh structures on the base plate 10, alternatively arranged according to columns, and insulated from each other. The first electrodes 32 can be electrically coupled to each other in a column along the first direction X, and the first electrodes 32 in a column along the second direction Y can be insulated from each other. The second electrodes 34 can be dispersed between the first electrodes 32, and can be formed in separate patterns in a column along the second direction Y. Thereby, the second electrodes 34 can be insulated from each other. In at least one embodiment, the indium tin oxide film 30 can be etched via a chemical etching method.

At block 904, the insulated layers are patterned on the first electrodes and the second electrodes via an ink jet printing method.

Each insulated layer 50 can be located on a portion of each two neighboring second electrodes 34 in a column along the second direction Y, and a portion of each two first electrodes 32 positioned adjacent to the two neighboring second electrodes 34. In at least one embodiment, the insulated layers 50 can be attached to the first electrodes 32 and the second electrodes 34.

At block 905, one conductive connector, composed conductive particles of ink doped with metal, is formed on each insulated layer via the ink jet printing method, and electrically coupled with the two neighboring second electrodes.

The conductive connectors 70 can be made of ink doped with silver nanoparticles, and the width of each conductive connector 70 can be about 30 μm to about 50 μm. In at least one embodiment, the conductive connectors 70 can be made of ink doped with gold or copper nanoparticles.

At block 906, the width of each conductive connector is reduced below about 10 μm via a laser processing method.

A laser device (not shown) can emit laser beams to the edge of one conductive connector 70. When a power density of the laser beams is more than a threshold power density of the conductive connector 70, the conductive connector 70 can be vaporized by the laser beams. In this way, the width of each conductive connector 70 can be reduced. The laser device can emit continuous laser beams to diminish the widths of the conductive connectors 70, and the wave length of the laser can be about 1064 nanometers. In at least one embodiment, the laser device can emit pulse laser beams to diminish the widths of the conductive connectors 70, and the wave length of the laser cannot be limited as above.

In at least one embodiment, the method can include a curing step after forming the indium tin oxide film 30, forming the insulated layers 50, or forming the conductive connectors 70, respectively. The corresponding film can be cured by one or more methods selected from the group consisting of room temperature curing, high temperature curing, and ultraviolet curing.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure, as defined by the appended claims.

What is claimed is:

1. A method for manufacturing a touch panel, the method comprising:
providing a base plate;
forming an indium tin oxide film on the base plate;
etching the indium tin oxide film to form a plurality of first and second electrodes which are alternatively arranged according to columns on the base plate and insulated from each other, the first electrodes in a column along a first direction being electrically coupled to each other, the second electrodes in a column along a second direction intersecting the first direction having separated patterns;
forming a plurality of insulated layers on the plurality of first and second electrodes, each insulated layer overlapping a portion of each two neighboring second electrodes in a column along the second direction and a portion of each two first electrodes positioned adjacent to the two neighboring second electrodes;
forming a plurality of conductive connectors on the plurality of insulated layers via an ink jet printing method to electrically interconnect with the second electrodes in a column along the second direction; and
diminishing the widths of the plurality of conductive connectors below 10 μm via a laser processing method.

2. The method of claim 1, wherein the width of each conductive connector after the step of forming the conductive connectors is in a range from about 30 μm to about 50 μm.

3. The method of claim 1, wherein continuous laser beams are employed in the step of diminishing the widths of the connectors to diminish the widths of the plurality of conductive connectors.

4. The method of claim 1, wherein plus laser beams are employed in the step of diminishing the widths of the connectors to diminish the widths of the plurality of conductive connectors.

5. The method of claim 1, wherein laser with the wave length of 1064 nanometers is employed in the step of diminishing the widths of the connectors to diminish the widths of the conductive connectors.

6. The method of claim 1, further comprising a step after forming the indium tin oxide film: solidifying the indium tin oxide film.

7. The method of claim 6, wherein the indium tin oxide film is solidified by one or more methods selected from the group consisting of a method of room temperature curing, a method of high temperature curing, and a method of ultraviolet curing.

8. The method of claim 1, further comprising a step after forming the insulated layers: solidifying the insulated layers.

9. The method of claim 8, wherein the insulated layers are solidified by one or more methods selected from the group consisting of a method of room temperature curing, a method of high temperature curing, and a method of ultraviolet curing.

10. The method of claim 1, wherein the method further comprises a step after forming the conductive connectors: solidifying the conductive connectors.

11. The method of claim 10, wherein the conductive connectors are solidified by one or more methods selected from the group consisting of a method of room temperature curing, a method of high temperature curing, and a method of ultraviolet curing.

12. The method of claim 1, wherein ink employed in the step of forming the plurality of conductive connectors is selected from the group consisting of ink doped with silver nanoparticles, ink doped with gold nanoparticles, and ink doped with copper nanoparticles.

13. The method of claim 1, wherein the indium tin oxide film is formed by a sputtering coating method.

14. The method of claim 1, wherein the insulated layers are formed by a method of ink jet printing.

15. A method for manufacturing a touch panel, the method comprising:
providing a base plate;
first forming a film of conductive material on the base plate;
etching the film to form a plurality of sections of substantially common shape and size in rows of a diamond matrix, each of the sections within a common row being electrically connected with each other and electrically isolated from adjacent ones of the sections in adjacent rows;
second forming, over each congruence of four sections from two adjacent rows, an insulating layer; and
third forming a conductive connector on top of each insulated layer to electrically connect two sections from adjacent rows;
wherein the first forming defines the sections as electrically connected rows and electrically isolated columns, and the third forming converts the electrically isolated columns into electrically connected columns.
